(19) United States
(12) Patent Application Publication
(10) Pub. No.: US 2016/0233858 A1
(43) Pub. Date: Aug. 11, 2016

(54) SWITCHING CIRCUIT AND SEMICONDUCTOR DEVICE

(71) Applicant: TOYOTA JIDOSHA KABUSHIKI KAISHA, Toyota-shi (JP)

(72) Inventors: Masaki WASEKURA, Toyota-shi (JP); Masaru SENOO, Okazaki-shi (JP); Ken TOSHIYUKI, Seto-shi (JP)

(73) Assignee: TOYOTA JIDOSHA KABUSHIKI KAISHA, Toyota-shi (JP)

(21) Appl. No.: 14/988,425

(22) Filed: Jan. 5, 2016

(30) Foreign Application Priority Data
Feb. 9, 2015 (JP) 2015-023313

(51) Int. Cl. H03K 17/567; H01L 29/739

(52) U.S. Cl. CPC H03K 17/567; H01L 29/7393

(57) ABSTRACT

A switching circuit includes a wiring having a parallel circuit of a first IGBT and a second IGBT. If a current of the wiring is relatively large, both of the first and second IGBTs are turned on at a turn-on timing and turned off at a turn-off timing. If the current is relatively small, one of the first and second IGBTs is turned on at the turn-on timing and turned off at the turn-off timing, and the other is maintained in an off state from a timing preceding the turn-off timing until the turn-off timing.

### CROSS-REFERENCE TO RELATED APPLICATION

This application claims priority to Japanese Patent Application No. 2015-023313 filed on Feb. 9, 2015, the entire contents of which are hereby incorporated by reference into the present application.

### TECHINICAL FIELD

The disclosed technology relates to a switching circuit.

### DESCRIPTION OF RELATED ART

Japanese Patent Application Publication No. 2004-112916 discloses a switching circuit utilizing a plurality of IGBTs (insulated-gate bipolar transistors). Large-current switching can be performed by the IGBTs.

### SUMMARY

In a switching circuit utilizing an IGBT, turn-off loss caused in the IGBT is problematic. Conventionally, it is known that a switching speed of the IGBT becomes fast by decreasing a gate resistance, and it is also known that the turn-off loss becomes small by increasing the switching speed (that is, by decreasing the gate resistance). However, the inventors have found that the above relationship between the switching speed and the turn-off loss is not satisfied when a current flowing through the IGBTs is small. That is, the inventors have found that reducing the turn-off loss of the IGBTs in a low current phase by decreasing the gate resistance is difficult. The present disclosure provides a new technology that reduces the turn-off loss of the IGBTs at a time of a low current.

The inventors have found that there is a relationship in which turn-off loss becomes smaller as a size of the IGBTs becomes small when a current flowing through the IGBTs is small. However, this relationship between the size of the IGBTs and the turn-off loss disappears when the current flowing through the IGBTs becomes large. In the technology disclosed herein, the turn-off loss of IGBTs is reduced by utilizing this phenomenon.

A switching circuit disclosed herein comprises a wiring, a parallel circuit and a controller. The parallel circuit of a first IGBT and a second IGBT is arranged in the wiring. The controller is configured to control the first and second IGBTs individually. The controller is configured to receive a signal indicating a turn-on timing and a turn-off timing. The controller is configured to execute a first control procedure and a second control procedure. In the first control procedure, both of the first and second IGBTs are turned on at the turn-on timing and turned off at the turn-off timing. In the second control procedure, a first target IGBT, which is one of the first and second IGBTs, is turned on at the turn-on timing and turned off at the turn-off timing, and a second target IGBT, which is the other of the first and second IGBTs, is maintained in an off state from a timing preceding the turn-off timing until the turn-off timing. The controller is configured to execute the first control procedure in a case where a current flowing through the wiring is larger than a threshold value, and execute the second control procedure in a case where the current flowing through the wiring is smaller than or equal to the threshold value.

According to another aspect, the second target IGBT is not turned on in the second control procedure in order to maintain the second target IGBT in the off-state in advance of the turn-off timing; alternatively, in the second control procedure, the second target IGBT is turned off prior to turning off the first target IGBT after both of the second target IGBT and the first target IGBT have been turned on. Moreover, according to one aspect, one of the first IGBT and the second IGBT always is selected as the second target IGBT and the other always is selected as the first target IGBT; alternatively, according to another aspect, it is possible to alternate between a period during which the first IGBT is the second target IGBT and a period during which the second IGBT is the second target IGBT.

Moreover, the controller may make a judgment as to which of the first control procedure and the second control procedure is to be executed, based on a current flowing through the wiring at the time of the judgment or at a point in time prior to the time of the judgment. Moreover, this judgment may be made depending on whether or not the current itself flowing through the wiring is larger than the threshold value, or depending on whether or not a predetermined value, which is calculated based on the current flowing through the wiring, is larger than the threshold value. For example, calculation can be made for a predicted value of a current flowing through the wiring from the current of the wiring at a point in time prior to the time of judgment, and the judgment may be made depending on whether or not the predicted value is larger than the threshold value.

In this switching circuit, switching the current flowing through the wiring is performed by the parallel circuit in which the first IGBT and the second IGBT are connected in parallel with each other. Moreover, in this switching circuit, the first control procedure and the second control procedure are executed based on the current flowing through the wiring.

When the current flowing through the wiring is relatively large, the first control procedure is executed. In the first control procedure, the first IGBT and the second IGBT are in an on-state from the turn-on timing to the turn-off timing. Accordingly, the current flows through both of the first IGBT and the second IGBT. When the current flowing through the wiring is large, the current can flow so as to be distributed to the first IGBT and the second IGBT by executing the first control procedure. Thereby, the load of the first IGBT and the second IGBT can be reduced. Moreover, the first IGBT and the second IGBT are turned off at the turn-off timing. In this case, the size of IGBT that is turned off is large because it is a combined size of the first IGBT and the second IGBT. However, in the first control procedure, since the current flowing through the wiring (that is, the first IGBT and the second IGBT) is large, there exists almost no correlation between the size of the IGBTs being turned off and the turn-off loss. Therefore, even if the first IGBT and the second IGBT are turned off in this way, very large turn-off loss does not occur.

When the current flowing through the wiring is relatively small, the second control procedure is executed. In the second control procedure, the second target IGBT is turned off in advance of the turn-off timing. Therefore, at the turn-off timing, the first target IGBT is turned off in a state where the second target IGBT has already been turned off. In this case, since the size of an IGBT that is turned off is the size of the first target IGBT, the size of the IGBT that is turned off is smaller compared with the size of the IGBTs in the case of the first control procedure. Since the current flowing through the wiring in the second control procedure is small, the turn-off loss can be reduced by turning off the first target IGBT in a state where the second target IGBT is in the off-state (that is, by decreasing the size of the IGBT that is turned off). Moreover, in the second control procedure, at least just before the turn-off timing, the second target IGBT is in the off-state and the first target IGBT is in the on-state. Accordingly, the current does not flow through the second target IGBT, but flows through the first target IGBT. However, since the current flowing through the wiring is small, even if a current flow is concentrated on the first target IGBT in this way, an excessive load is never applied to the first target IGBT.

In this way, according to this switching circuit, the turn-off loss at the time of a small current can be reduced (by using one of IGBTs, which is smaller than both of the IGBTs) while the load of each IGBT is being reduced at the time of a large current (because both IGBTs are used when there is a large current).

### BRIEF DESCRIPTION OF DRAWINGS

FIG. 1 is a circuit diagram of an inverter circuit;

FIG. 2 is a circuit diagram of a switching circuit;

FIG. 3 is a top view of a semiconductor substrate (a hatched region shows IGBTs);

FIG. 4 is a graph showing variation with time for each value in a first embodiment;

FIG. 5 is a graph showing variation with time for each value in a second embodiment;

FIG. 6 is a graph showing variation with time for each value in a third embodiment;

FIG. 7 is a graph showing variation with time for each value in a fourth embodiment;

FIG. 8 is a top view of the semiconductor substrate (a hatched region shows IGBTs) of a modification; and

FIG. 9 is a top view of the semiconductor substrate (hatched regions show IGBTs) of another modification.

### DETAILED DESCRIPTION

### First Embodiment

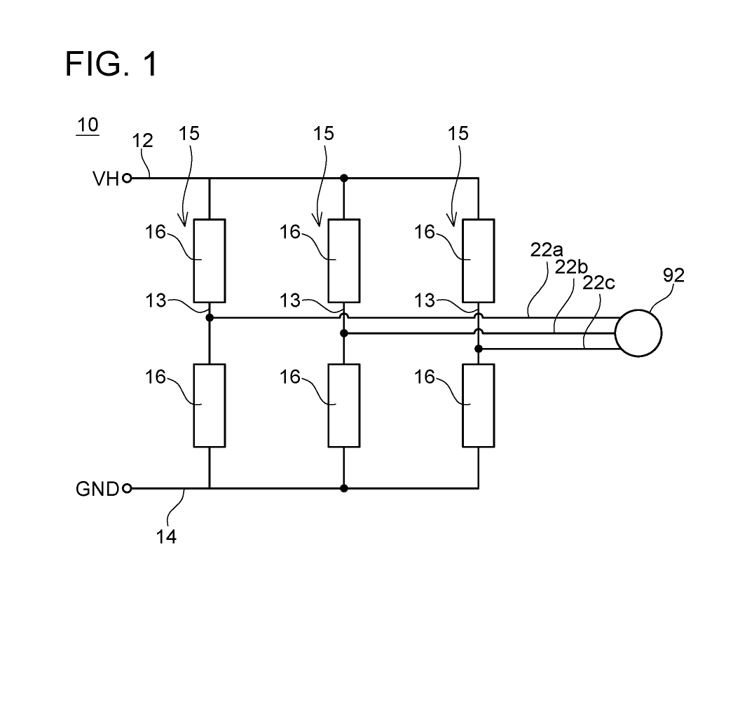

The inverter circuit 10 of the first embodiment, shown in FIG. 1, supplies an alternating current to a motor 92. The inverter circuit 10 has a high-potential wiring 12 and a low-potential wiring 14. The high-potential wiring 12 and the low-potential wiring 14 are connected to a direct-current power source that is not illustrated. A positive potential VH is applied to the high-potential wiring 12, and a ground potential (0 V) is applied to the low-potential wiring 14. Three series circuits 15 are connected in parallel with each other between the high-potential wiring 12 and the low-potential wiring 14. Each of the series circuits 15 has a connecting wiring 13, which is connected between the high-potential wiring 12 and the low-potential wiring 14, and two switching circuits 16 interposed in the connecting wiring 13. The two switching circuits 16 are connected in series between the high-potential wiring 12 and the low-potential wiring 14. Output wirings 22a to 22c are connected to the connecting wiring 13, which is positioned between the two switching circuits 16 connected in series. The other end of each of the output wirings 22a to 22c is connected to the motor 92. The inverter circuit 10 supplies a three-phase alternating current to the motor 92, by making each of the switching circuits 16 perform a switching operation.

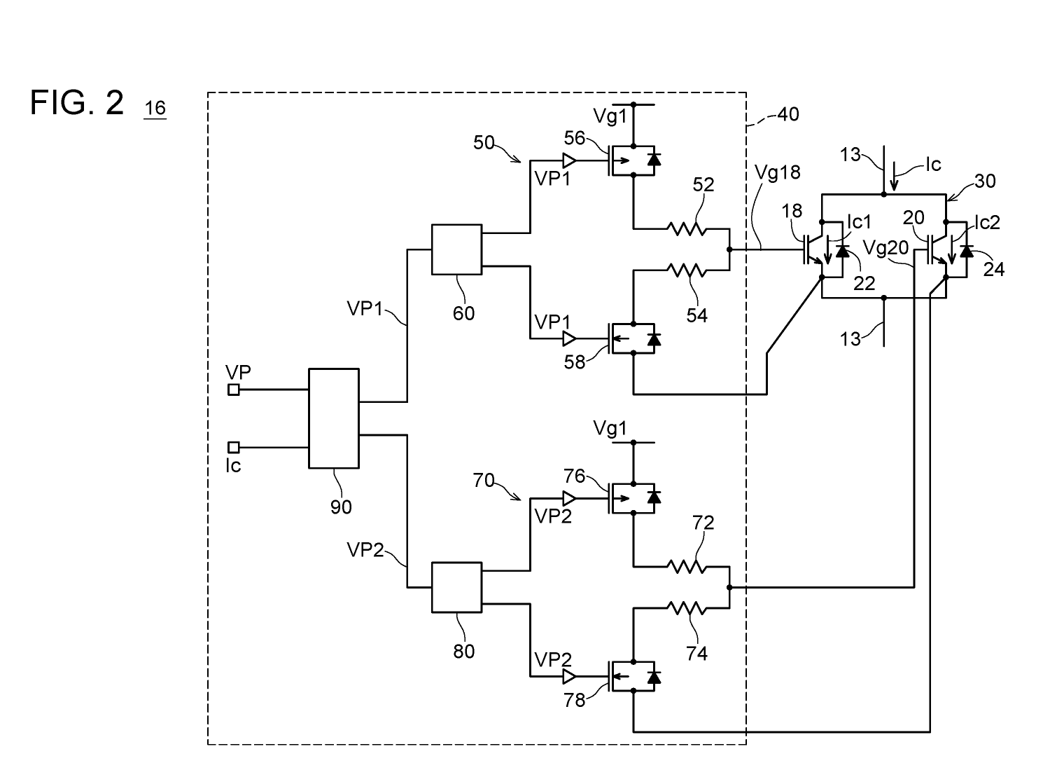

FIG. 2 shows an internal circuit of one of the switching circuits 16. The configuration of each of the switching circuits 16 is equal to each other. As shown in FIG. 2, the switching circuit 16 has an IGBT (insulated-gate bipolar transistor) 18 and an IGBT 20. The IGBT 18 and the IGBT 20 are connected in parallel with each other. That is, a collector of the IGBT 18 is connected to a collector of the IGBT 20, and an emitter of the IGBT 18 is connected to an emitter of the IGBT 20. A parallel circuit 30 is constituted by the two IGBTs 18 and 20, which are connected in parallel with each other. The parallel circuit 30 is interposed in the connecting wiring 13. The parallel circuit 30 has diodes 22, 24. The diodes 22, 24 are connected to the IGBTs 18, 20, respectively, in a reverse parallel manner. That is, an anode of the diode 22 is connected to the emitter of the IGBT 18. A cathode of the diode 22 is connected to the collector of the IGBT 18. An anode of the diode 24 is connected to the emitter of the IGBT 20. A cathode of the diode 24 is connected to the collector of the IGBT 20.

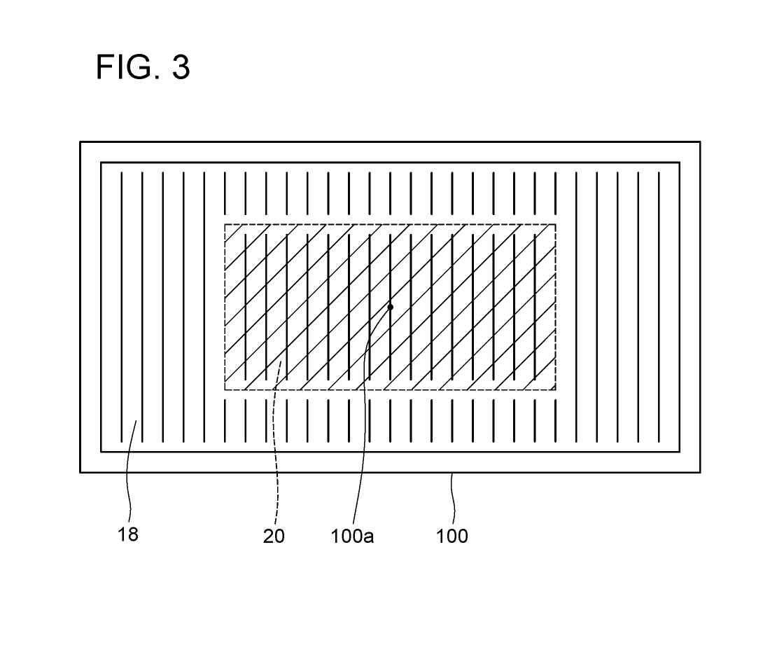

As shown in FIG. 3, the IGBT 18 and the IGBT 20 are formed on a single semiconductor substrate 100. When an upper surface of the semiconductor substrate 100 is viewed in a plan view, the IGBT 20 is formed in a range including a center 100a of the semiconductor substrate 100, and the IGBT 18 is formed around the IGBT 20. The emitter of the IGBT 18 and the emitter of the IGBT 20 are connected to a common emitter electrode. The collector of the IGBT 18 and the collector of the IGBT 20 are connected to a common collector electrode. The gate electrode of the IGBT 18 is separated from the gate electrode of the IGBT 20. Therefore, the gate potential of the IGBT 18 can be controlled such that it differs from the gate potential of the IGBT 20. That is, the gate potential of the IGBT 18 and the gate potential of the IGBT 20 can be individually controlled.

The switching circuit 16 of FIG. 2 has a gate control circuit 40. The gate control circuit 40 controls the gate potential Vg18 of the IGBT 18 and the gate potential Vg20 of the IGBT 20. The gate control circuit 40 has a logic control circuit 90, a level shifter 60, a level shifter 80, a control circuit 50, and a control circuit 70.

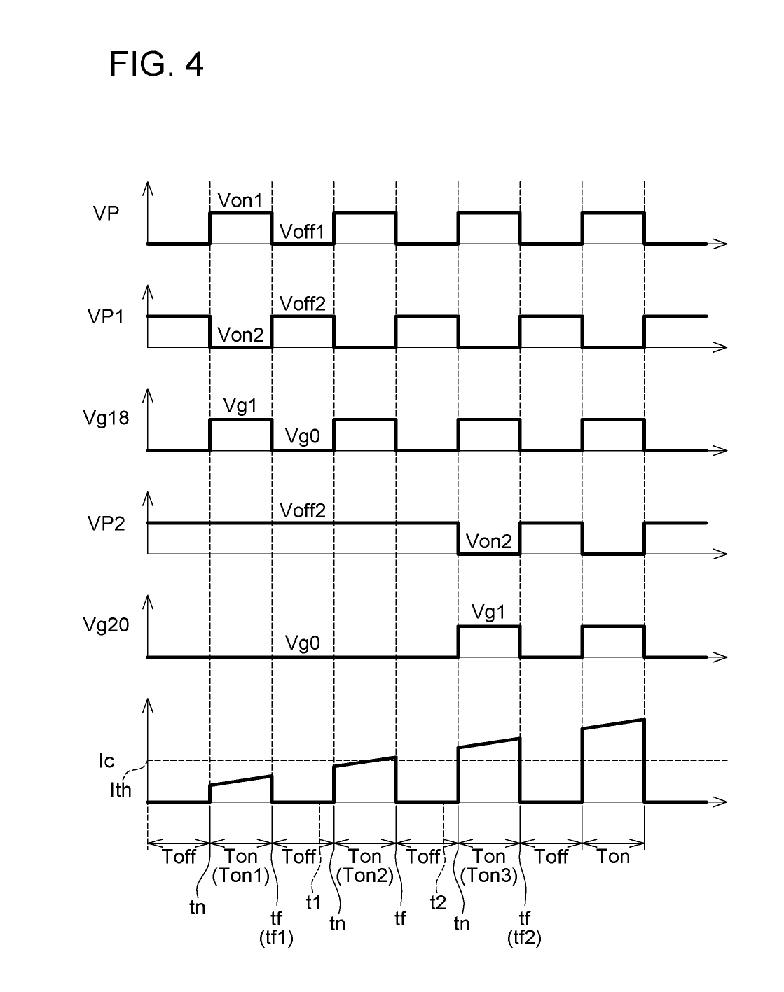

A PWM (pulse width modulated) signal VP is inputted from the outside into the logic control circuit 90. As shown in FIG. 4, the PWM signal VP is a pulse signal that performs transition between a high potential Von1 and a low potential Voff1. A duty ratio of the PWM signal VP varies according to operation condition of a motor 92.

Moreover, a value of a current Ic flowing through the connecting wiring 13 is inputted into the logic control circuit 90. A collector current Von1 of the IGBT 18 can be measured from the potential of a detecting electrode (an electrode for detecting a collector current) of the IGBT 18, which is not illustrated. Moreover, a collector current Ic2 of the IGBT 20 can be measured from the potential of the detecting electrode (not illustrated) of the IGBT 20. A current Ic flowing through the connecting wire 13 can be measured by adding the collector current Ic1 and the collector current Ic2. The current Ic may be measured by another method.

The logic control circuit 90 outputs a driving signal VP1 and a driving signal VP2 based on the inputted PWM signal VP and the current Ic. As shown in FIG. 4, the driving signal VP1 and the driving signal VP2 are pulse signals which perform transition between a low potential Von2 and a high potential Voff2. Explanations will be made later in detail on the waveform of the driving signals VP1, VP2.

The level shifter 60 is connected to the logic control circuit 90 and the control circuit 50. The level shifter 60 modifies a reference potential of the driving signal VP1 outputted from the logic control circuit 90. The driving signal VP1, the reference potential of which was modified, is inputted into the control circuit 50.

The control circuit 50 controls the gate potential Vg18 of the IGBT 18 based on the driving signal VP1 inputted from the level shifter 60. The control circuit 50 has a gate-on resistance 52, a gate-off resistance 54, a PMOS 56, and an NMOS 58. One end of the gate-on resistance 52 is connected to the gate of the IGBT 18. The other end of the gate-on resistance 52 is connected to a drain of the PMOS 56. A source of the PMOS 56 is connected to a gate-on potential Vg1. The gate-on potential Vg1 is higher than an emitter potential of the IGBT 18, and is higher than a gate threshold value of the IGBT 18 (the minimum gate potential required for turning on the IGBT 18). The driving signal VP1 is inputted into a gate of the PMOS 56. One end of the gate-off resistance 54 is connected to the gate of the IGBT 18. The other end of the gate-off resistance 54 is connected to the drain of the NMOS 58. The source of the NMOS 58 is connected to the emitter of the IGBT 18. The driving signal VP1 is inputted into the gate of the NMOS 58. As shown in FIG. 4, the driving signal VP1 is a signal which performs transition between the high potential Voff2 and the low potential Von2. While the driving signal VP1 is in the low potential Von2, the PMOS 56 is in an on-state, and the NMOS 58 is in an off-state. Therefore, the gate potential Vg18 of the IGBT 18 becomes the gate-on potential Vg1, and the IGBT 18 is in the on-state. While the driving signal VP1 is in the high potential Voff2, the NMOS 58 is in the on-state and the PMOS 56 is in the off-state. Therefore, the gate potential Vg18 of the IGBT 18 become a potential Vg0 that is almost equal to the potential of the emitter of the IGBT 18, and the IGBT 18 is in the off-state. In this way, the control circuit 50 makes the IGBT 18 perform switching operation according to the driving signal VP1.

The level shifter 80 is connected to the logic control circuit 90 and the control circuit 70. The level shifter 80 modifies the reference potential of the driving signal VP2 outputted from the logic control circuit 90. The driving signal VP2, the reference potential of which was modified, is inputted into the control circuit 70.

The control circuit 70 controls the gate potential Vg20 of the IGBT 20 based on the driving signal VP2 inputted from the level shifter 80. The control circuit 70 has a gate-on resistance 72, a gate-off resistance 74, a PMOS 76, and an NMOS 78. One end of the gate-on resistance 72 is connected to the gate of the IGBT 20. The other end of the gate-on resistance 72 is connected to the drain of the PMOS 76. The source of the PMOS 76 is connected to the gate-on potential Vg1. The driving signal VP2 is inputted into the gate of the PMOS 76. One end of the gate-off resistance 74 is connected to the gate of the IGBT 20. The other end of the gate-off resistance 74 is connected to the drain of the NMOS 78. The source of the NMOS 78 is connected to the emitter of the IGBT 20. The driving signal VP2 is inputted into the gate of the NMOS 78. As shown in FIG. 4, the driving signal VP2 is a signal which performs transition between the high potential Voff2 and the low potential Von2. While the driving signal VP2 is in the low potential Von2, the PMOS 76 is in the on-state and the NMOS 78 is in the off-state. Therefore, the gate potential Vg20 of the IGBT 20 becomes the gate-on potential Vg1, and the IGBT 20 is in the on-state. While the driving signal VP2 is in the high potential Voff2, the NMOS 78 is in the on-state and the PMOS 76 is in the off-state. Therefore, the gate potential Vg20 of the IGBT 20 becomes the potential Vg0 that is almost equal to the potential of the emitter of the IGBT 20, and the IGBT 20 is in the off-state. In this way, the control circuit 70 makes the IGBT 20 perform switching operation according to the driving signal VP2.

Next, explanations will be made in detail on the operation of the switching circuit 16. As shown in FIG. 4, the PWM signal VP, which performs transition between the high potential Von1 and the low potential Voff1, is inputted into the logic control circuit 90. The high potential Von1 is a signal that means setting the switching circuit 16 into the on-state, and the low potential Voff1 is a signal that means setting the switching signal 16 into the off-state. Therefore, a timing at which the PWM signal VP performs transition from the low potential Voff1 to the high potential Von1 is a turn-on timing tn at which the switching circuit 16 is turned on. Moreover, a timing at which the PWM signal VP performs transition from the high potential Von1 to the low potential Voff1 is a turn-off timing tf at which the switching circuit 16 is turned off. Moreover, hereafter, a period during which the PWM signal VP is in the high potential Von1 is called an on-period Ton, and a period during which the PWM signal VP is in the low potential Voff1 is called an off-period Toff.

The logic control circuit 90 outputs a signal, the waveform of which is the inverted waveform of the PWM signal VP, as a driving signal VP1. That is, while the PWM signal VP is in the high potential Von1, the driving signal VP1 is the low potential Von2; while the PWM signal VP is in the low potential Voff1, the driving signal VP1 is the high potential Voff2. Therefore, in the on-period Ton, the gate potential Vg18 becomes the gate-on potential Vg1, and the IGBT 18 is set to the on-state. Accordingly, in the on-period Ton, the current Ic flows at least via the IGBT 18. In the off-period Toff, the gate potential Vg18 becomes the gate-off potential Vg0, and the IGBT 18 is put into the off-state.

Moreover, the logic control circuit 90 outputs the high potential Voff 2 as the driving signal VP2 during the off-period Toff. Accordingly, in the off-period Toff, the gate potential Vg20 becomes the gate-off potential Vg0, and the IGBT 20 is set to the off-state. During the off-period Toff, since both the IGBT 18 and the IGBT 20 are in the off-state, the current Ic does not flow. During the off-period Toff, the logic control circuit 90 judges whether or not the IGBT 20 is to be turned on in a next on-period Ton. In more detail, during the off-period Toff, the logic control circuit 90 judges whether or not the current Ic was larger than a threshold value Ith at the last turn-off timing tf of an immediately preceding on-period Ton. In a case where the current Ic was equal to or smaller than the threshold value Ith, the second control procedure is executed. In the second control procedure, the logic control circuit 90 maintains the driving signal VP2 at the high potential Voff2 in a next on-period Ton. On the other hand, in a case where the current Ic was larger than the threshold value Ith, the first control procedure is executed. In the first control procedure, the logic control circuit 90 makes the driving signal VP2 perform transition to the low potential Von2 in a next turn-on timing tn, and maintains the driving signal VP2 at the low potential Von2 during the on-period Ton. For example, at a timing t1 in FIG. 4 (at a timing during the off-period Toff), the logic control circuit 90 judges that the current Ic was smaller than the threshold value Ith in an immediately preceding on-period Toni. Then, the logic control circuit 90 executes the second control procedure, and maintains the driving signal VP2 at the high potential Voff2 in a next on-period Ton2. Accordingly, the IGBT 20 is maintained in the off-state in the on-period Ton2. Therefore, the current Ic flows only via the IGBT 18 in the on-period Ton2. In the case of FIG. 4, the current Ic exceeds the threshold value Ith during the on-period Ton2. Accordingly, at a timing t2 during a next off-period Toff, the logic control circuit 90 judges that the current Ic was larger than the threshold value Ith at the turn-off timing tf of an immediately preceding on-period Ton2. Then, the logic control circuit 90 executes the first control procedure. That is, the logic control circuit 90 makes the driving signal VP2 perform transition to the low potential Von2 at a next turn-on timing tn. The driving signal VP2 is maintained at the low potential Von2 during an on-period Ton3. Accordingly, the IGBT 20 is put into the on-state in the on-period Ton3. That is, the current Ic flows via the IGBTs 18 and 20 in the on-period Ton3. The IGBTs 18 and the 20 are simultaneously turned off at the last turn-off timing tf2 of the on-period Ton3. In this way, in this switching circuit 16, when the current Ic flowing though the connecting wiring 13 is small, only the IGBT 18 is turned on in the on-period Ton; when the current Ic is large, both of the IGBTs 18 and 20 are turned on in the on-period Ton.

When the IGBTs 18, 20 are turned off, turn-off loss occurs. When the current Ic is small, there appears a correlation between the turn-off loss and the size of an IGBT that is turned off. That is, as the size of the IGBT that is turned off becomes small, the turn-off loss becomes smaller. When the current Ic is large, there hardly appears a correlation like this. Why the above correlation changes according to an amount of the current Ic in this way is thought to be due to the following reason. The turn-off loss occurs because carriers (electrons and holes) existing in the semiconductor substrate of the IGBT just before turning-off are discharged from the semiconductor substrate at the time of turning-off. A number of electrons which exist in the semiconductor substrate while the current Ic is flowing becomes larger as the current Ic becomes large. On the other hand, regardless of whether or not the current Ic is large, holes exist in a saturated state in the semiconductor substrate if the current Ic flows. That is, a number of the holes, which exist in the semiconductor substrate while the current Ic is flowing, is substantially constant regardless of the amount of the current Ic. Therefore, when the current Ic is small, the turn-off loss occurs mainly due to the influence of the holes. As mentioned above, since the holes exist in a saturated state in a region, through which the current Ic is flowing, of the semiconductor substrate, the number of the holes at this time is substantially proportional to the size of the IGBT (that is, an area of the region through which the current Ic is flowing in the semiconductor substrate). Therefore, when the current Ic is small, a correlation appears between the turn-off loss and the size of the IGBT that is turned off. On the other hand, when the current Ic is large, since the number of electrons existing in the semiconductor substrate becomes large, it becomes that the turn-off loss occurs mainly due to an influence of electrons. Accordingly, when the current Ic is large, there exists almost no correlation between the turn-off loss and the size of the IGBT that is turned off.

As mentioned above, when the current Ic is small, the switching circuit 16 does not turn on the IGBT 20, but turns on only the IGBT 18 in the on-period Ton. That is, the IGBT 20 is turned off in advance of the turn-off timing tf, and the IGBT 18 is turned off at the turn-off timing tf. Therefore, only the IGBT 18 is turned off at the turn-off timing tf (for example, at the turn-off timing tf1 of FIG. 4). When only the IGBT 18 is turned off, since a size of a region in which turning-off is performed in the semiconductor substrate 100 (that is, an area of a region of the IGBT 18 in FIG. 3) is small, the turn-off loss becomes small. Moreover, when the current Ic is small, even though the current Ic flows only through the IGBT 18 in the on-period Ton, a very high load is not applied to the IGBT 18. In this way, when the current Ic is small, with only the IGBT 18 being turned off at the turn-off timing tf, the turn-off loss can be reduced while an excessive load is prevented from being applied to the IGBT 18.

Moreover, as mentioned above, when the current Ic is large, the switching circuit 16 turns on both of the IGBTs 18 and 20 in the on-period Ton. That is, the switching circuit 16 turns on both of the IGBTs 18 and 20 at the turn-on timing tn, and turns off both of the IGBTs 18 and 20 at the turn-off timing. Therefore, the current Ic flowing through the connecting wiring 13 is distributed to the IGBTs 18 and 20. In this way, when the current Ic is large, with the current Ic flowing through the IGBTs 18 and 20 in a distributed manner, a high load can be prevented from being applied to the IGBTs 18 and 20. Moreover, both the IGBTs 18 and 20 are turned off at the turn-off timing tf (for example, the turn-off timing tf2 of FIG. 4). In this case, the size of a region in which turning-off is performed in the semiconductor substrate 100 is an area that is a sum of the area of the IGBT 18 and the area of the IGBT 20 in FIG. 3. That is, in this case, a region in which turning-off is performed is large. However, when the current Ic is large, there exists almost no correlation between the size of an IGBT that is turned off and the turn-off loss. Therefore, if the IGBT 18 and the IGBT 20 are simultaneously turned off in this way, turn-off loss does not become large when compared with a case where only either one of them is turned off. In this way, when the current Ic is large, with both of the IGBTs 18 and 20 turned on in the on-period Ton, the load of the IGBTs 18 and 20 can be reduced without increasing the turn-off loss.

As is clear from the above explanations, in this switching circuit 16, an energization time (that is, time in an on-state) of the IGBT 18 is longer than the energization time of the IGBT 20. Moreover, as shown in FIG. 3, the IGBT 20 is formed in a central part of the semiconductor 100, and the IGBT 18 is formed around the IGBT 20. The IGBT 18 formed in a peripheral side has higher heat radiation performance than that of the IGBT 20 formed in the central part. In this way, making the energizing time of the IGBT 18, which has high heat radiation performance, long, temperature rise of the semiconductor substrate 100 can be suitably suppressed.

### Second Embodiment

The switching circuit of the second embodiment has the same configuration as the switching circuit of the first embodiment shown in FIG. 2 except for a part of a control method. The switching circuit of the second embodiment performs control in the same manner as the switching circuit of the first embodiment when the current Ic is large. That is, when the current Ic is large, both of the IGBTs 18 and 20 are turned on in the on-period Ton and both of the IGBTs 18 and 20 are turned off in the off-period Toff. When the current Ic is small, the switching circuit of the second embodiment executes a control method different from the control method of the first embodiment.

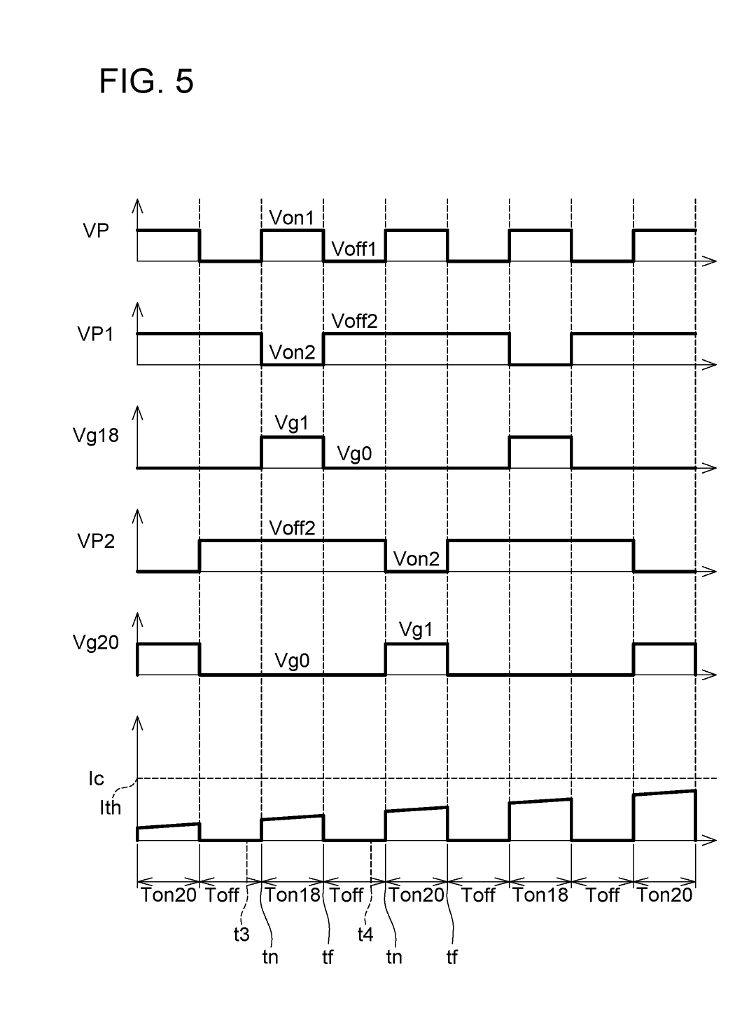

The switching circuit of the second embodiment executes the second control procedure shown in FIG. 5 when the current Ic is small. That is, when the current Ic is small, the logic control circuit 90 controls the IGBT 18 and the IGBT 20 so that an on-period Ton 18 during which only the IGBT 18 is turned on and an on-period Ton 20 during which only the IGBT 20 is turned on may alternately occur. In more detail, control is performed so that the on-period Ton 18, the off-period Toff, the on-period Ton 20, and the off-period Toff may repeatedly appear in this order. In the off-period Toff, both of the IGBT 18 and the IGBT 20 are in the off-state. For example, at a timing t3 of FIG. 5, the logic control circuit 90 judges that the current Ic was smaller than the threshold value Ith in an immediately preceding on-period Ton 20. Then, in a next on-period Ton 18, the logic control circuit 90 sets the IGBT 18 into the on-state and maintains the IGBT 20 in the off-state. Since the current Ic has not increased to the threshold value Ith in this on-period Ton 18, at a timing t4, the logic control circuit 90 judges that the current Ic was smaller than the threshold value Ith in an immediately preceding on-period Ton 18. Then, in a next on-period Ton 20, the logic control circuit 90 turns on the IGBT 20, and maintains the IGBT 18 in the off-state. In this way, the logic control circuit 90 turns on one of the IGBTs 18 and 20, which had not been turned on in the last on-period Ton, in the next on-period Ton. Accordingly, when the current Ic is small, the IGBT 18 and the IGBT 20 are alternately turned on. With the IGBT 18 and the IGBT 20 alternately turned on in this way, heat produced in the semiconductor 100 can be dispersed. Thereby, the temperature rise of the semiconductor substrate 100 can be suppressed. Moreover, also in a configuration like this, when the current Ic is small, since only one of the IGBT 18 or the IGBT 20 is selectively turned off at the turn-off timing tf, turn-off loss can be reduced.

### Third Embodiment

The switching circuit of the third embodiment has the same configuration as that of the switching circuit of the first embodiment shown in FIG. 2 except for a part of a control method. The switching circuit of the third embodiment performs control in the same manner as the switching circuit of the first embodiment when the current Ic is large. When the current Ic is small, the switching circuit of the third embodiment executes a control method different from the control method of the first embodiment.

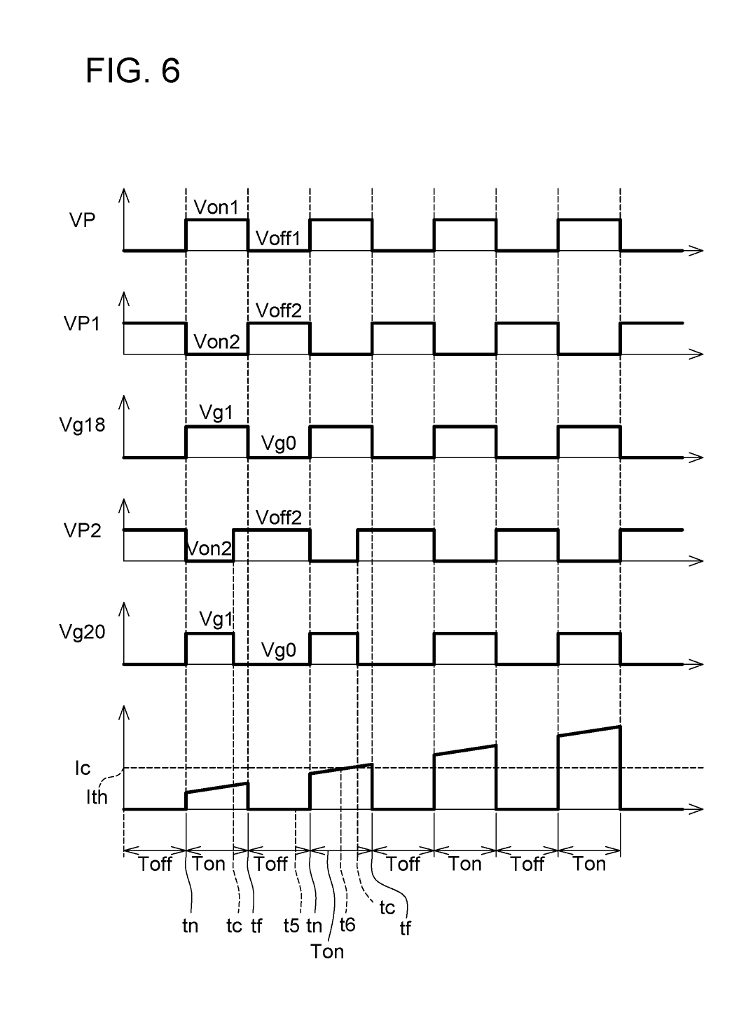

The switching circuit of the third embodiment executes the second control procedure shown in FIG. 6, when the current Ic is small. The logic control circuit 90 turns on both of the IGBTs 18 and 20 at the turn-on timing tn even when the current Ic is small. Then, the IGBT 20 is turned off at a timing tc just before the turn-off timing tf. After that, the logic control circuit 90 maintains the IGBT 20 in the off-state until a next turn-on timing tn (that is, until the turn-off timing tf elapses). Therefore, only the IGBT 18 is turned off at the turn-off timing tf. For example, at the timing t5 of FIG. 6, the logic control circuit 90 judges that the current Ic was smaller than the threshold value Ith in an immediately preceding on-period Ton. Then, the logic control circuit 90 turns on both of the IGBTs 18 and 20 at a next turn-on timing tn. And the logic control circuit 90 turns off the IGBT 20 at the timing tc before the turn-off timing tf. The IGBT 20 is maintained in the off-state until the turn-off timing tf elapses. At the timing tc, the IGBT 18 is not turned off and is maintained in the on-state. The IGBT 18 is turned off at a turn-off timing tf after that. Therefore, at the turn-off timing tf, the IGBT 18 is independently turned off. In this way, in the third embodiment, when the current Ic is small, both the IGBTs 18 20 are turned on in a part of the on-period Ton, while the IGBT 20 is turned off prior to the IGBT 18.

In the above control, while the IGBT 20 is turned off at the timing tc, the IGBT 18 is maintained in the on-state. Even when the IGBT 20 is turned off, since the IGBT 18 is in the on-state, a voltage between the collector and the emitter of the IGBT 20 is maintained low. Therefore, the turn-off loss does not occur when the IGBT 20 is turned off. Moreover, when the IGBT 18 is turned off at the turn-off timing tf, a voltage between the collector and the emitter of the IGBT 18 rises with the IGBT 20 turned off. Therefore, the turn-off loss occurs at the turn-off timing tf. However, since only the IGBT 18 is turned off at the turn-off timing tf, the turn-off loss is small. Therefore, the turn-off loss can be reduced also in the switching circuit of the third embodiment. Moreover, also when the current Ic is small, with the current Ic distributed to the IGBTs 18 and 20 in a part of the on-period Ton, the load of the IGBTs 18 and 20 can further be reduced. Thereby, the temperature rise of the semiconductor substrate 100 can be suppressed.

In the third embodiment mentioned above, judgment on the current Ic was made by the logic control circuit 90 at a timing in the off-period Toff (for example, at the timing t5). However, in the third embodiment, judgment on the current Ic may be made at a timing in the on-period Ton (for example, at a timing t6, that is, at a timing before the timing tc at which the IGBT 20 is turned off). In this case, judgment can be made based on the current Ic at the point in time of the timing t6.

Moreover, in the third embodiment mentioned above, a delay time, which is a time interval between the timing tc at which the IGBT 20 is turned off and the turn-off timing tf at which the IGBT 18 is turned off, is preferably enough time for carriers in the region of the IGBT 20 in the semiconductor 100 to disappear. On the other hand, the delay time mentioned above is preferably 10% or less of the on-period Ton in order to minimize influence on the control.

Moreover, in the third embodiment mentioned above, the IGBT 18 and IGBT 20 are simultaneously turned on at the turn-on timing tn. However, the turn-on timing of the IGBT 20 may be later than the turn-on timing tn.

### Fourth Embodiment

The switching circuit of the fourth embodiment has the same configuration as that of the switching circuit of the first embodiment shown in FIG. 2 except for a part of a control method. The switching circuit of the fourth embodiment performs control in the same manner as the switching circuit of the first embodiment when the current Ic is large. When the current Ic is small, the switching circuit of the fourth embodiment executes a control method different from the control method of the first embodiment.

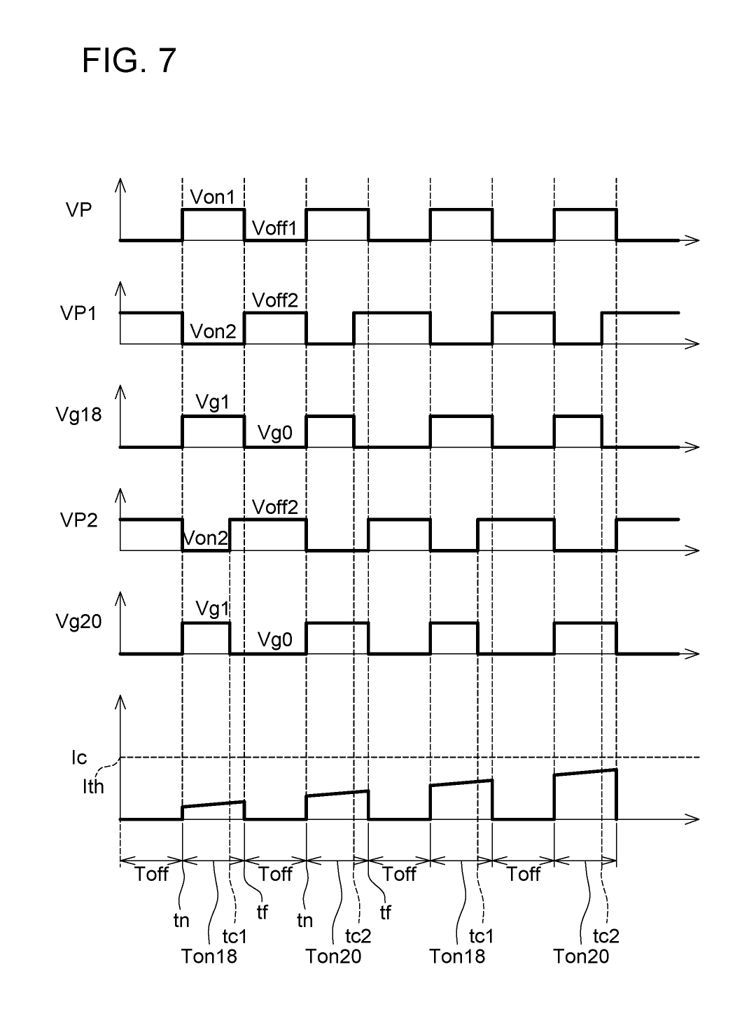

When the current Ic is small, the control method of the fourth embodiment combines the control method of the second embodiment and the control method of the third embodiment. In the fourth embodiment, when the current Ic is small, the second control procedure shown in FIG. 7 is executed. In FIG. 7, control is performed so that the on-period Ton18, the off-period Toff, the on-period Ton20, and the off-period Toff may repeatedly appear in this order. Both of the IGBTs 18 and 20 are turned on at the turn-on timing tn. In the early part of the on-period Ton18, the IGBT 18 and the IGBT 20 are in the on-state. At a timing tc1 in the on-period Ton18, the IGBT 20 is turned off. The IGBT 18 is turned off at a next turn-off timing tf. The IGBT 18 and the IGBT 20 are in the off-state in the off-period Toff. Both of the IGBT 18 and the IGBT 20 are turned on at a next turn-on timing tn. In the early part of the on-period Ton20, the IGBTs 18 and 20 are in the on-state. At a timing tc2 in the on-period Ton20, the IGBT 18 is turned off. The IGBT 20 is turned off at a next turn-off timing tf. According to a configuration like this, since the on-period Ton18, in which the energization time of the IGBT 18 is long, and the on-period Ton20, in which the energization time of the IGBT 20 is long, alternately appear, heat produced in the semiconductor substrate 100 can be dispersed.

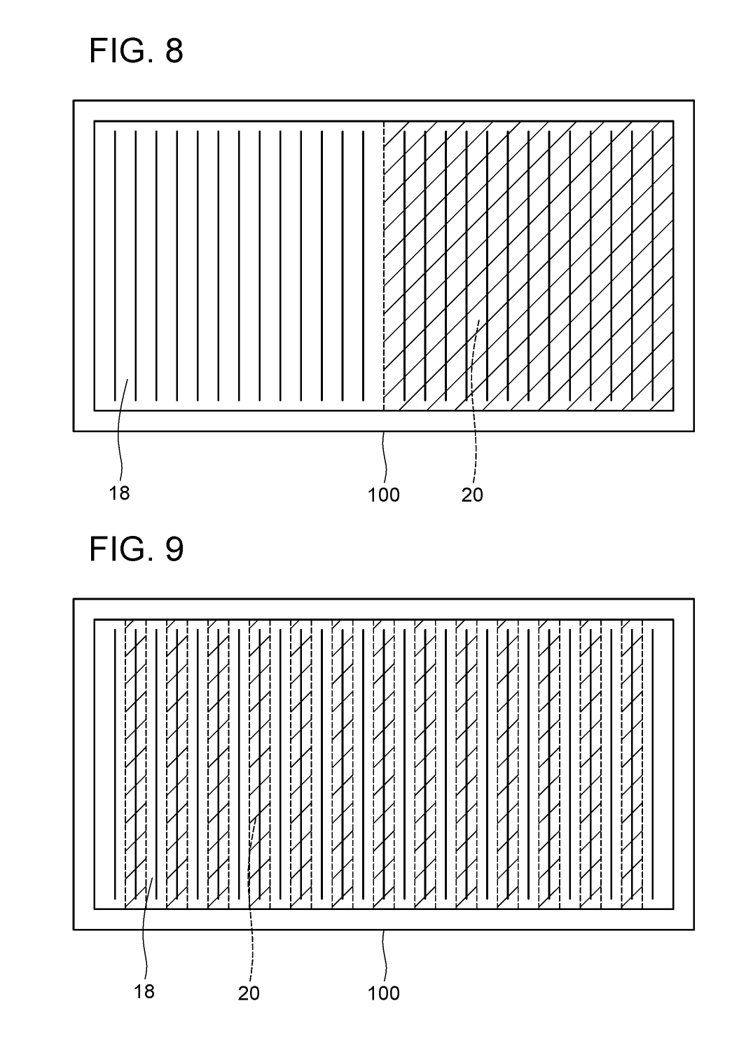

In the first-fourth embodiments, as shown in FIG. 3, the IGBT 20 is provided in the central part of the semiconductor substrate 100, and the IGBT 18 is provided around the IGBT 20. However, the IGBTs 18 and 20 may be adjacent to each other as shown in FIG. 8. Moreover, as shown in FIG. 9, the IGBTs 18 20, both of which are stripe-shaped, may be provided alternately. In the configuration of FIG. 9, heat which is produced when either of the IGBT 18 or the IGBT 20 is selectively being turned on can be dispersed. Moreover, the IGBTs 18 and 20 may be separately provided on different substrates. However, if the IGBTs 18 and 20 are separately provided on different substrates, the loss occurring in the parallel circuit 30 may become large because parasitic resistance and parasitic inductance, which are produced in a wiring connecting the IGBT 18 and the IGBT 20, become large. Therefore, it is more preferable that the IGBTs 18 and 20 are provided on a single semiconductor substrate.

Moreover, the switching circuit in the first-fourth embodiments mentioned above performs switching between the second control procedure and the first control procedure, depending on whether or not the current Ic in an immediately preceding on-period Ton is larger than the threshold value Ith. Alternatively, switching between the second control procedure and the first control procedure may be performed based on a predicted value of the current Ic of a next on-period Ton. The predicted value can be calculated based on the current Ic during an immediately preceding on-period Ton.

Explanations will be made below on a relationship between the elements of each embodiment and the elements of claims. The IGBT 18 of the first-fourth embodiments is an example of the claimed first IGBT. The IGBT 20 of the first-fourth embodiments is an example of the claimed second IGBT. The wiring 13 of the first-fourth embodiments is an example of the claimed wiring. The control circuit 40 of the first-fourth embodiments is an example of the claimed controller. The PWM signal VP of the first-fourth embodiments is an example of the claimed signal indicating a turn-on timing and a turn-off timing.

The IGBT 20 of the first embodiment is an example of the claimed second target IGBT. The IGBT 18 of the first embodiment is an example of the claimed first target IGBT. The second control procedure of the first embodiment is an example of the claimed second control procedure in which the second target IGBT is not turned on at the turn-on timing.

In the on-period Ton18 of the second embodiment, the IGBT 20 is an example of the claimed second target IGBT, and the IGBT 18 is an example of the claimed first target IGBT. In the on-period Ton20 of the second embodiment, the IGBT 18 is an example of the claimed second target IGBT, and the IGBT 20 is an example of the claimed first target IGBT. The second control procedure of the second embodiment is an example of the claimed second control procedure in which the first IGBT and the second IGBT are alternately selected as the second target IGBT. Moreover, the second control procedure of the second embodiment is an example of the claimed second control procedure in which the second target IGBT is not turned on at the turn-on timing.

The IGBT 20 of the third embodiment is an example of the claimed second target IGBT. The IGBT 18 of the third embodiment is an example of the claimed first target IGBT. The second control procedure of the third embodiment is an example of the claimed second control procedure in which the second target IGBT is turned on during a part of a period from the turn-on timing to the turn-off timing.

In the on-period Ton18 of the fourth embodiment, the IGBT 20 is an example of the claimed second target IGBT, and the IGBT 18 is an example of the claimed first target IGBT. In the on-period Ton20 of the fourth embodiment, the IGBT 18 is an example of the claimed second target IGBT, and the IGBT 20 is an example of the claimed first target IGBT. The second control procedure of example 4 is an example of the claimed second control procedure in which the first IGBT and the second IGBT are alternately selected as the second target IGBT. The second control procedure of the fourth embodiment is an example of the claimed second control procedure in which the second target IGBT is turned on during a part of a period from the turn-on timing to the turn-off timing.

The technical aspects disclosed herein will be listed below. Each of the technical aspects below provides usefulness independently.

In the technique disclosed herein, the second target IGBT may not be turned on at the turn-on timing in the second control procedure.

According to this configuration, since the second target IGBT is not turned on while the current flowing through the wiring is small, control is easily performed.

In the technique disclosed herein, the second IGBT may be the second target IGBT.

According to this configuration, since the second IGBT is always the second target IGBT, control is easily performed.

In the technique disclosed herein, the first and second IGBTs may alternately be selected as the second target IGBT.

According to this configuration, the heating regions of the IGBTs can be distributed.

In the technique disclosed herein, the second target IGBT may turn on during a part of a period from the turn-on timing to the turn-off timing in the second control procedure.

According to this configuration, since the second target IGBT is turned on in a part of a period during which the first target IGBT is in the on-state, the load of the first target IGBT can be reduced.

In the technique disclosed herein, the first and second IGBTs may be provided in a common semiconductor substrate.

In the aforementioned technique in which the second IGBT is always selected as the second target IGBT, the first and second IGBTs may be provided in a common semiconductor substrate, the second IGBT may be provided in a location including a center of the semiconductor substrate, and the first IGBT may be provided around the second IGBT.

According to this configuration, the temperature rise of the IGBTs can be suppressed.

Another technique disclosed herein as an example is a semiconductor device comprising a common semiconductor substrate, a common emitter electrode, and a common collector electrode. In the common semiconductor substrate, a first IGBT and a second IGBT are provided. A turn-on timing and a turn-off timing of the first and second IGBTs are controllable individually. The common emitter electrode is connected to an emitter of the first IGBT and to an emitter of the second IGBT. The common collector electrode is connected to a collector of the first IGBT and to a collector of the second IGBT.

The embodiments have been described in detail in the above. However, these are only examples and are not intended to limit the claims. The claims are intended to encompass various modifications and changes of the concrete examples described above. The technical aspects explained herein exert technical utility independently or in various combinations, and the combinations are not limited to those described in the claims as filed. Moreover, the aspects exemplified in the present disclose achieve a plurality of objects at the same time, and have technical utility by achieving one or more of such objects.

What is claimed is:

1. A switching circuit comprising:
a wiring including a parallel circuit, the parallel circuit including a first IGBT and a second IGBT in parallel; and
a controller configured to control the first and second IGBTs individually,
wherein the controller is configured to receive a signal indicating a turn-on timing and a turn-off timing, and execute a first control procedure and a second control procedure,
in the first control procedure, both of the first and second IGBTs are turned on at the turn-on timing and turned off at the turn-off timing,
in the second control procedure, a first target IGBT, which is one of the first and second IGBTs, is turned on at the turn-on timing and turned off at the turn-off timing, and a second target IGBT, which is the other of the first and second IGBTs, is maintained in an off state from a timing preceding the turn-off timing until the turn-off timing, and
the controller is configured to execute the first control procedure in a case where a current flowing through the wiring is larger than a threshold value, and execute the second control procedure in a case where the current flowing through the wiring is equal to or smaller than the threshold value.

2. The switching circuit of claim 1, wherein the second target IGBT is not turned on at the turn-on timing in the second control procedure.

3. The switching circuit of claim 2, wherein the second IGBT always is the second target IGBT.

4. The switching circuit of claim 3, wherein
the first and second IGBTs are provided in a common semiconductor substrate,
the second IGBT is provided in a location including a center of the common semiconductor substrate, and
the first IGBT is provided surrounding the second IGBT.

5. The switching circuit of claim 2, wherein the first and second IGBTs are alternately selected as the second target IGBT.

6. The switching circuit of claim 1, wherein the second target IGBT is turned on during only a part of a period from the turn-on timing to the turn-off timing in the second control procedure.

7. The switching circuit of claim 6, wherein the second IGBT always is the second target IGBT.

8. The switching circuit of claim 7, wherein
the first and second IGBTs are provided in a common semiconductor substrate,
the second IGBT is provided in a location including a center of the common semiconductor substrate, and
the first IGBT is provided surrounding the second IGBT.

9. The switching circuit of claim 6, wherein the first and second IGBTs are alternately selected as the second target IGBT.

10. The switching circuit of claim 1, wherein the first and second IGBTs are provided in a common semiconductor substrate.

11. A semiconductor device comprising:
a common semiconductor substrate that includes a first IGBT and a second IGBT, wherein a turn-on timing and a turn-off timing of each of the first and second IGBTs are controllable individually;
a common emitter electrode connected to an emitter of the first IGBT and to an emitter of the second IGBT; and
a common collector electrode connected to a collector of the first IGBT and to a collector of the second IGBT.

12. The semiconductor device of claim 11, wherein the first IGBT and the second IGBT are parallel to each other in a circuit.

13. The semiconductor device of claim 11, further comprising:
a controller configured to control the first and second IGBTs individually,
wherein the controller is configured to receive a signal indicating a turn-on timing and a turn-off timing, and execute a first control procedure and a second control procedure,
in the first control procedure, both of the first and second IGBTs are turned on at the turn-on timing and turned off at the turn-off timing,
in the second control procedure, a first target IGBT, which is one of the first and second IGBTs, is turned on at the turn-on timing and turned off at the turn-off timing, and a second target IGBT, which is the other of the first and second IGBTs, is maintained in an off state from a timing preceding the turn-off timing until the turn-off timing, and
the controller is configured to execute the first control procedure in a case where a current flowing through the wiring is larger than a threshold value, and execute the second control procedure in a case where the current flowing through the wiring is equal to or smaller than the threshold value.

14. The semiconductor device of claim 12, further comprising:
a controller configured to control the first and second IGBTs individually,
wherein the controller is configured to receive a signal indicating a turn-on timing and a turn-off timing, and execute a first control procedure and a second control procedure,
in the first control procedure, both of the first and second IGBTs are turned on at the turn-on timing and turned off at the turn-off timing,
in the second control procedure, a first target IGBT, which is one of the first and second IGBTs, is turned on at the turn-on timing and turned off at the turn-off timing, and a second target IGBT, which is the other of the first and second IGBTs, is maintained in an off state from a timing preceding the turn-off timing until the turn-off timing, and
the controller is configured to execute the first control procedure in a case where a current flowing through the wiring is larger than a threshold value, and execute the second control procedure in a case where the current flowing through the wiring is equal to or smaller than the threshold value.

15. The semiconductor device of claim 11, wherein
the second IGBT is provided in a location including a center of the common semiconductor substrate, and
the first IGBT is provided surrounding the second IGBT.
